(19) United States
(12) Patent Application Publication
(10) Pub. No.: US 2022/0384138 A1
(43) Pub. Date: Dec. 1, 2022

(54) ELECTRON BEAM WELDING SYSTEMS EMPLOYING A PLASMA CATHODE

(71) Applicant: US Electron, Inc., Irving, TX (US)

(72) Inventors: John Noonan, Naperville, IL (US); Dean Walters, Naperville, IL (US)

(21) Appl. No.: 17/808,147

(22) Filed: Jun. 22, 2022

Related U.S. Application Data
(63) Continuation of application No. 17/769,664, filed on Jan. 1, 0001.
(60) Provisional application No. 62/916,214, filed on Oct. 16, 2019.

(51) Int. Cl. H01J 37/077; H01J 37/315; H01J 37/18; B23K 15/06

(52) U.S. Cl. CPC H01J 37/077; H01J 37/315; H01J 37/18; B23K 15/06; H01J 2237/182; H01J 2237/049; H01J 2237/188; H01J 2237/06366

(57) ABSTRACT

In an embodiment, a system is provided that includes an electron gun, a focusing system, and a housing. The electron gun can include a cold cathode electron source and an extraction electrode. The focusing system can be configured to focus a beam of electrons extracted from the electron gun to a focal region. The housing can include the electron gun and extend along a housing axis in the direction of the electron beam. The cold cathode source is configured to emit electrons at a first operating pressure that is higher than a second operating pressure at the focal region of the electron beam.

### CROSS-REFERENCE TO RELATED APPLICATIONS

This application is a continuation of U.S. Ser. No. 17/769,664, filed Apr. 15, 2022, entitled “Electron Bean Welding Systems Employing a Plasma Cathode,” which is a national stage entry, filed under 35 U.S.C. § 371, of International Patent Application No. PCT/US2020/056043 filed on Oct. 16, 2020, which claims the benefit of U.S. Provisional Patent Application No. 62/916,214, filed on Oct. 16, 2019 and entitled “Electron Beam Welding Systems Employing A Plasma Cathode.” The entire contents of these applications are incorporated by reference herein in their entireties.

### BACKGROUND

Welding is a process by which a work piece including two components are joined together. In general, surfaces of the two components are placed in contact with one another and heated. The heat causes the two components to melt and, when subsequently cooled, fuse together.

Electron-beam welding (EBW) is one technique that has been developed to heat metal components for welding. High velocity electrons are extracted from a source and focused into a beam. The focal region of the electron beam is directed to the weld location where surfaces of the two metal components are in contact. A portion of the kinetic energy of the electrons within the beam is converted into thermal energy, supplying heat for the welding process.

EBW provides a number of advantages. In one aspect, electron beams can exhibit a relatively high penetration depth-to-width ratio, which can eliminate the need to perform multiple passes. In another aspect, electron beams can be focused with high accuracy, providing precise control and reproducibility. The energy of an electron beam can also be tailored to avoid overheating the weld region, reducing shrinkage and distortion.

Existing EBW systems typically employ thermionic cathodes as an electron source. However, thermionic cathodes can present challenges. As an example, thermionic cathodes require relatively high vacuum (e.g., about 10⁻⁴ torr or lower) to operate. At higher pressures, the thermionic cathode can react with residual gases in the vacuum and form compounds that readily erode the thermionic cathode due to evaporation. This erosion reduces the lifespan of the thermionic cathode. Additionally, in order to maintain the thermionic cathode at high vacuum, the components to be joined, as well as work piece fixturing and positioning mechanisms, must be installed in a large welding chamber that is also under high vacuum. Enclosing the fixturing and positioning mechanisms in vacuum increases the cost, complexity, and size of EBW systems, as compared to other welding technologies. In addition to these lifespan and cost limitations, there are also limits to the electron currents that can be generated by thermionic cathodes. The electron current can restrict the depth and extent of welding and the types of materials that can be welded.

### SUMMARY

Embodiments of the present disclosure provide improved systems and methods for electron beam welding. As discussed in greater detail below, the hot thermionic cathode is replaced with a cold plasma cathode. The cold plasma cathode is relatively inert at operating temperatures without substantive erosion. As a result, the lifespan of the plasma cathode can be significantly increased (e.g., more than 30 times). The inert nature of the plasma cathode also enables operation at pressures that are significantly higher than conventional thermionic cathodes. As a result, in one embodiment in which the plasma cathode gun is retrofit into the welding chamber containing the work piece, the welding chamber can also be maintained at higher pressure than e-beam welders with thermionic cathodes. For example, the weld chamber pressure can operate between about 1 millitorr and about 50 millitorr without significant electron beam scatter from residual gases. In another embodiment, in which the plasma cathode gun is installed in a differentially pumped housing (referred to as a snorkel), the welding chamber to be eliminated. The components to be welded and the support table and fixturing are positioned outside, rather than within, the vacuum enclosure. The components, support table, and fixturing are at atmospheric pressure. With the welding chamber outside of the vacuum enclosure, the volume of the vacuum enclosure can be significantly reduced, providing a reduction in the cost and complexity of plasma cathode-based EBW systems, as compared to thermionic cathode-based EBW systems.

In an embodiment, a system is provided that includes an electron gun, a focusing system, and a housing. The electron gun can include a cold cathode electron source and an extraction electrode. The focusing system can be configured to focus a beam of electrons extracted from the electron gun to a focal region. The housing can include the electron gun and extend along a housing axis in the direction of the electron beam. The cold cathode source is configured to emit electrons at a first operating pressure that is higher than a second operating pressure at the focal region of the electron beam.

In another embodiment, the cold cathode electron source is a plasma cathode. The plasma cathode can include a plasma cathode chamber, a first plasma electrode, and a second plasma electrode. The first plasma electrode can be mounted to a first wall of the plasma cathode chamber. The second plasma electrode can be mounted to a second wall of the plasma cathode chamber, opposite the first wall. An axis of the plasma cathode chamber can extend in the direction between the first and second plasma electrodes.

In another embodiment, the plasma cathode can be configured to generate a plasma having an electron temperature less than about 200° C.

In another embodiment, the plasma cathode chamber axis can be approximately aligned with the housing axis.

In another embodiment, the plasma cathode chamber axis can be approximately perpendicular to the housing axis.

In another embodiment, the first operating pressure can be within the range from about 50 millitorr to about 500 millitorr.

In another embodiment, the second operating pressure can be within the range from about 1 millitorr to about 50 millitorr.

In another embodiment, the housing can include the electron gun and a welding chamber enclosing the focal region.

In another embodiment, the housing can further include a differentially pumped snorkel extending between a first end coupled to the electron gun and a second free end. The snorkel can be configured to provide a selected pressure gradient between the first end and the second end, and the focal region can be approximately positioned at the second free end.

In another embodiment, the snorkel can include a plurality of vacuum enclosures, each in fluid communication with a respective vacuum pump.

In an embodiment, a method is provided. The method can include generating, by an electron gun including a cold cathode source and an extraction electrode, electrons at a first pressure. The method can further include extracting, by the extraction electrode, electrons emitted from the cold cathode source. The method can additionally include focusing a beam of the extracted electrons to a focal region along an axis of a housing containing the electron gun. The method can further include receiving, incident upon a surface of the work piece the focal region of the electron beam, wherein a second pressure at the work piece is less than the first pressure.

In another embodiment, generating the electrons can include receiving a flow of gas within a plasma cathode chamber of the electron gun, and generating an electric field between a first plasma electrode mounted to a first wall of the plasma cathode chamber and a second plasma electrode mounted to a second wall of the plasma cathode chamber, opposite the first wall. The electric field can be configured to form a plasma from the gas and an axis of the plasma cathode chamber can extend in the direction between the first and second plasma electrodes.

In another embodiment, the generated plasma can have an electron temperature less than about 200° C.

In another embodiment, the plasma cathode chamber axis can be approximately aligned with the housing axis.

In another embodiment, the plasma cathode chamber axis can be approximately perpendicular to the housing axis.

In another embodiment, the first pressure can be within the range from about 50 millitorr to about 500 millitorr.

In another embodiment, the second pressure can be within the range from about 1 millitorr to about 50 millitorr.

In another embodiment, the method can further include enclosing the work piece within a welding chamber. The welding chamber can be in fluid communication with the electron gun.

In another embodiment, the method can further include forming a vacuum seal between a surface of the work piece and a free end of a snorkel, the snorkel extending from the free end to the electron gun. The method can also include establishing a selected pressure gradient along the length of the snorkel between the electron gun and the free end.

In another embodiment, establishing the selected pressure gradient can include applying vacuum pressure of different levels to respective vacuum enclosures of the snorkel.

### DESCRIPTION OF DRAWINGS

These and other features will be more readily understood from the following detailed description taken in conjunction with the accompanying drawings, in which:

FIG. 1 is a diagram illustrating one exemplary embodiment of an electron beam welding system including a housing containing a hot thermionic cathode;

FIG. 2 is a diagram illustrating a first exemplary embodiment of an operating environment including an electron beam welding system including a cold plasma cathode positioned within a first plasma cathode chamber aligned with the housing (e.g., along the z-axis);

FIG. 3 is a diagram illustrating a second exemplary embodiment of an electron beam welding system including a cold plasma cathode positioned within a second plasma cathode chamber oriented approximately perpendicular to the housing (e.g., along the x-axis);

FIG. 4 is a diagram illustrating a third exemplary embodiment of an electron beam welding system including a cold plasma cathode and a differentially pumped housing; and

FIG. 5 is a diagram illustrating an operating environment including the beam welding system of FIGS. 2-4.

It is noted that the drawings are not necessarily to scale. The drawings are intended to depict only typical aspects of the subject matter disclosed herein, and therefore should not be considered as limiting the scope of the disclosure.

### DETAILED DESCRIPTION

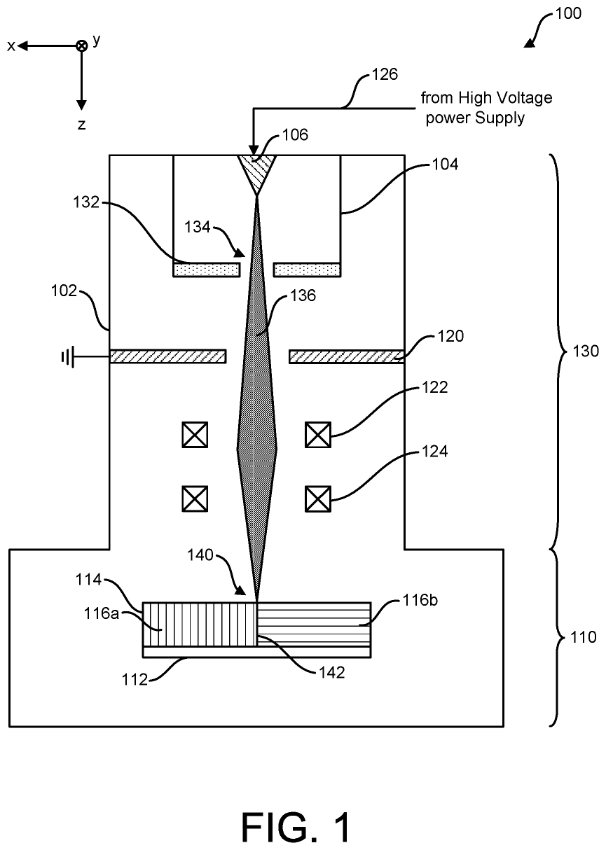

To better appreciate the features and advantages of embodiments of the disclosed cold plasma cathode-based EBW systems, as compared to hot thermionic cathode-based EBW systems, an exemplary embodiment of a thermionic cathode-based EBW system 100 is discussed below with reference to FIG. 1. As shown, the thermionic cathode-based EBW system 100 includes a housing 102 containing a cathode chamber 104, the thermionic cathode 106 positioned within the cathode chamber 104, and a welding chamber 110 containing a stage 112. The stage 112 can be configured to secure and position a work piece 114 including a first component 116a and a second component 116b to be joined. An anode 120, a focusing coil 122, and a deflection coil 124 are interposed between the cathode chamber 104 and the welding chamber 110. The thermionic cathode 106 is in electrical communication with a high-voltage power supply (not shown) via a cable 126. The thermionic cathode 106, the focusing coil 122, the deflection coil 124, and the anode 120 can be collectively referred to as a thermionic electron gun 130.

The thermionic cathode 106 can take the form of a filament (e.g., a tungsten “hair-pin” filament). In use, an electric current from the high-voltage power supply is transmitted through the thermionic cathode 106, resulting in resistive heating of the thermionic cathode 106 and emission of electrons therefrom. The thermionic cathode 106 is biased at a large negative voltage, for example, within the range from about 60 kV to about 150 kV. An extractor electrode 132 is aligned in close proximity to the thermionic cathode 106 and is biased at a large positive voltage, within the range from about +400 V to about +1000 V, relative to the thermionic cathode 106. The extractor electrode 132 has an aperture 134 that accelerates the thermionic electrons towards the anode 120 (e.g., in the z-direction), which is at approximately ground potential, forming an electron beam (thermionic e-beam) 136. The thermionic e-beam 136 is transmitted through the anode 120 at high energy towards the focusing and deflection coils 122, 124. The focusing coil 122 generates a first magnetic field that is configured to focus the thermionic e-beam 136 to a focal region 140 of predetermined size (e.g., diameter) at a surface of the work piece 114 (e.g., an incipient weld location at the interface between the first component 116a and the second component 116b). The deflection coil 124 generates a second magnetic field that is configured to control in-plane deflection of the thermionic e-beam 136 (e.g., in the x-y plane). In this manner, the thermionic e-beam 136 forms a weld 142 joining the first component 116a and the second component 116b.

As noted above, the thermionic cathode 106 is heated to generate electrons. Therefore, the thermionic cathode 106 is classified as a “hot cathode.” However, at typical operating temperatures (e.g., about 1200° C.), the thermionic cathode 106 is highly reactive and easily forms compounds with gases present in the cathode chamber 104. Formation of these compounds is undesirable, as they reduce the level of electron emission and readily evaporate, as compared to the pure cathode material. Thus, the lifespan of the thermionic cathode 106 is limited by its evaporation rate. As an example, assuming a typical rate of evaporation, when the thermionic cathode 106 is maintained at a pressure of approximately 10⁻⁴ torr, its lifespan is limited to roughly 30 hours.

The lifespan of the thermionic cathode 106 can be increased by reducing the pressure in the cathode chamber 104. However, maintaining high vacuum pressure within the electron gun 130 requires that the welding chamber 110 is also enclosed and maintained under high vacuum. Thus, reducing the pressure in the cathode chamber 104 also requires a concurrent reduction of the pressure in the welding chamber 110. As an example, in order to maintain a pressure of the thermionic cathode 106 at about 10⁻⁵ torr, the welding chamber 110 is maintained at a pressure of about 10⁻⁴ torr. The need to maintain high vacuum in both the cathode chamber 104 and the welding chamber 110 can make electron beam welding relatively expensive compared to other joining and fabrication techniques.

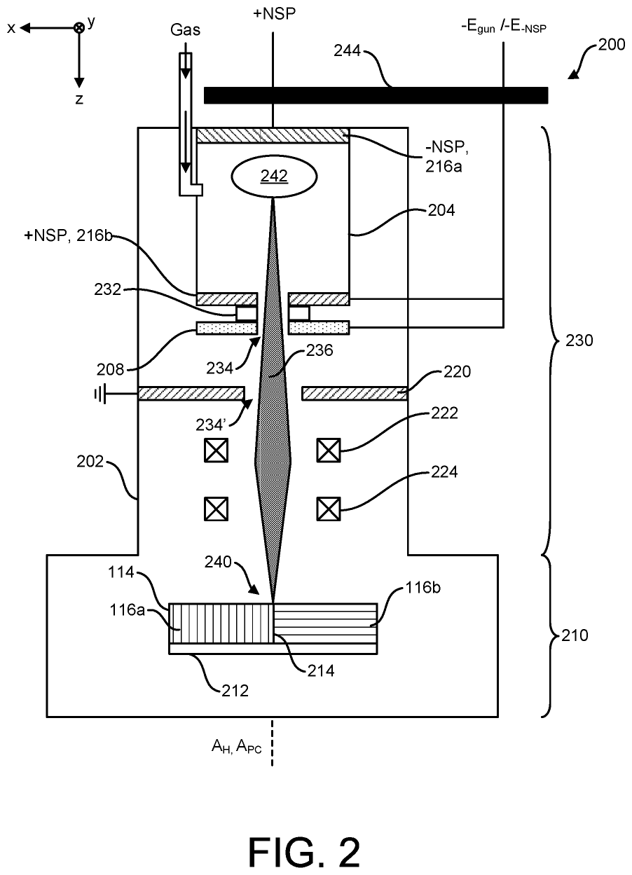

FIGS. 2-4 illustrate embodiments of plasma cathode-based EBW systems which replace the thermionic cathode 106 of the thermionic cathode-based EBW system 100 with a plasma cathode. As discussed in greater detail below, the plasma cathode can operate at significantly higher pressure than the thermionic cathode. For example, as discussed in greater detail below, in normal welding conditions the plasma cathode can operate at pressures from about 50 millitorr (0.05 torr) up to about 500 millitorr (0.5 torr), which is at least two to three orders of magnitude higher than the operating pressure of thermionic cathodes 106 (e.g., ≤10⁻⁴ torr) in current electron beam welding systems such as thermionic cathode-based EBW system 100. As a result the lifetime of a plasma cathode can be greater than 1,000 hours (e.g., more than 30 times that of a thermionic cathode).

Additionally, eliminating the requirement of high vacuum within the plasma cathode chamber also reduces the time required to pump down the welding chamber, simplifying the system's vacuum pump requirements, and increasing the rate of the system's processing time (e.g., throughput). For example, in normal welding operations, the welding chamber can operate at pressures less than or equal to about 10 millitorr (e.g., from about 1 millitorr up to about 10 millitorr. The operating parameters of the disclosed embodiments (e.g., plasma pressure, electrode bias, pulse frequency, pulse width, etc.) can also be changed to achieve high beam current and attendant improvements in weld speed, component throughput, and cost.

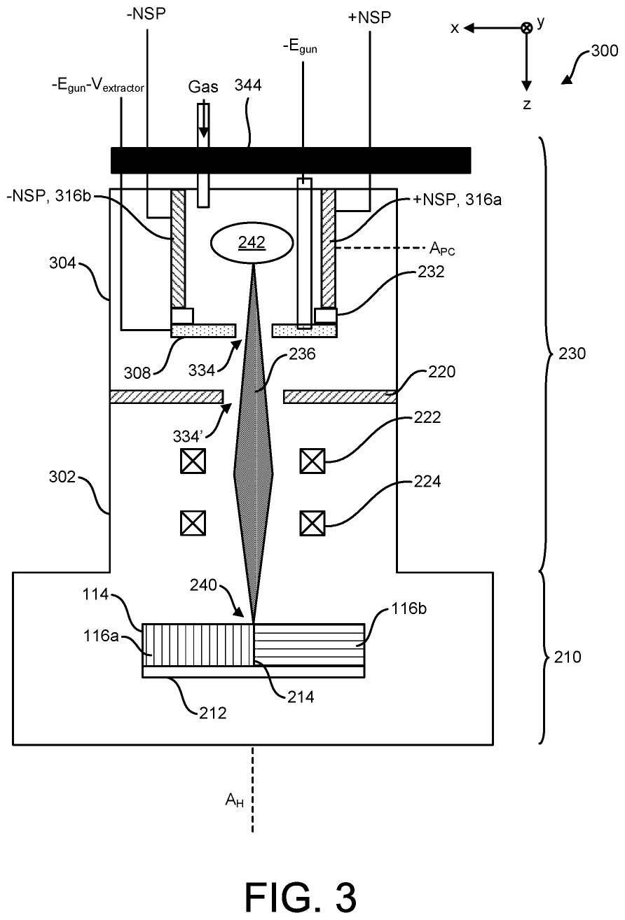

In certain embodiments, the pressure of the cathode chamber can be higher than that at the focal region of the plasma electron beam (e.g., within the welding chamber). That is, the pressure gradient between the cathode chamber and the welding chamber in EBW systems employing the plasma cathode can be reversed as compared to EBW systems employing a thermionic cathode. In certain embodiments, discussed with regards to FIGS. 2-3, the pressure gradient between the welding chamber and the plasma cathode can be achieved without differential pumping, because there is a differentially pumped orifice between the plasma cathode chamber and the welding chamber.

FIG. 2 illustrates a first embodiment of a plasma cathode-based EBW system 200 including a housing 202 containing the plasma cathode. The plasma cathode-based EBW system 200 further includes an anode 220, an extractor electrode 208, a focusing coil 222, and a deflection coil 224 within a plasma electron gun portion 230 of the housing 202. The stage 212 and the work piece 114 can be positioned in a welding chamber portion 210 of the housing 202, adjacent to the plasma electron gun portion 230.

As shown, in FIG. 2, the plasma cathode can include a plasma cathode chamber 204 of the plasma electron gun portion 230 of the housing 202. The plasma cathode can further include two plasma electrodes, a positive nanosecond plasma (NSP) electrode 216b, also referred to herein as +NSP electrode 216b, and a negative nanosecond plasma electrode 216a, also referred to herein as −NSP electrode 216a. The plasma electrodes 216a, 216b, are positioned on opposing sides of the plasma cathode chamber 204 and are configured for electrical communication with a high-voltage plasma power supply (not shown). An insulator 232 (e.g., a ceramic) is interposed between the extractor electrode 208 and the adjacent plasma electrode (e.g., the +NSP electrode 216b). The extractor electrode 208, the anode 220, the focusing coil 222, the deflection coil 224, and the stage 212 can operate as discussed above with respect to the thermionic cathode-based EBW system 100 of FIG. 1.

The plasma power supply can be a pulsed, high-voltage alternating current AC power supply. As an example, the power voltage can be ±E_{NSP}=about ±15 kV to about ±24 kV, with a 20 kHz frequency, and a few nanosecond pulse length.

In use, a neutral gas (also referred to as an inert gas) is supplied to the plasma cathode chamber 204. As an example, the neutral gas can be argon. Other examples of the neutral gas can include helium, nitrogen, and hydrogen. Combinations of two or more neutral gases can also be employed. The pressure within the plasma cathode chamber 204 can be within the range from about 50 millitorr to about 500 millitorr for normal welding operation.

Concurrently, the plasma power supply applies a potential difference between the plasma electrodes 216a, 216b. The potential difference generates an electric field between the plasma electrodes 216a and 216b. The pulsed voltage creates a discharge in the neutral gas to generate a plasma 242 (e.g., a cloud of electrons and ions. A high, negatively biased electrode (referred herein as −E_{gun}) is positioned at an extraction opening or aperture 234 in the plasma cathode chamber 204. Electrons are extracted from the plasma 242 with an additional electrode that is positively biased relative to the negatively biased extractor electrode. A portion of the plasma electrons formed in this manner can be extracted and collimated by the extractor electrode 208.

The temperature of the plasma 242 is less than about 200° C. under operating conditions and can be classified as a “cold cathode.” In contrast, a typical operating temperature of the hot thermionic cathode 106 can be about 1200° C. Due to its lower operating temperature, the plasma cathode exhibits significantly smaller thermal emittance than the thermionic cathode 106. As a result, the plasma electrons extracted from the plasma cathode, and collimated by the aperture 214 of the extractor electrode 208, can exhibit a lower beam emittance (also referred to as beam divergence) than the thermionic cathode 106. Thus, a focal region 240 of a plasma electron beam (plasma e-beam) generated using the plasma cathode can have a smaller diameter at the weld, allowing achievement of more precise welds.

Embodiments of the plasma cathode chamber can adopt a variety of configurations. FIG. 2 illustrates a first configuration in which the +NSP electrode 216b and the −NSP electrode 216a are separated from one another along the z-direction. A plasma chamber axis A_{PC} extends in the direction between the +NSP electrode 216b and the —NSP electrode 216a. A housing axis A_{H} of the housing 202 extends in the direction of the electron beam 236 (e.g., the z-direction). Accordingly, in this first configuration, and the plasma chamber axis A_{PC} is approximately aligned with the housing axis A_{H}. The +NSP electrode 216b is in electrical communication with a negative electron gun potential −E_{gun} applied to the extractor electrode 208. −E_{gun} can be selected within the range from −60 kV to about −150 kV. The −NSP electrode 216a is connected to the other output of the plasma power supply.

An advantage of this first configuration of the plasma cathode chamber 204 is that it requires three high-voltage feedthroughs, one each for the —NSP electrode 216a, the +NSP electrode 216b, and the extractor electrode 208. As the thermionic cathode-based EBW system 100 of FIG. 1 also employs three high-voltage vacuum feedthroughs, this first configuration of the plasma cathode chamber 204 can reuse the electron gun flange 244 and housing 202.

However, this first configuration of the plasma cathode chamber 204 can also face challenges with regards to the plasma power supply. Notably, the plasma power supply has voltage isolation of the output voltages but the pulsing can be asymmetric. The pulse can be unbalanced relative to the plasma power supply common because the positive plasma electrode +NSP 216b is connected to −E_{gun}. This can cause the isolation transformer to shift the average bias voltage, creating a virtual common of unknown voltage and necessitate modification of the plasma power supply. One way to affect this modification can be by the use of a fast switching transformer to reduce the transformer's inductance and allow the stored energy to be dissipated sufficiently quickly to bring the virtual common to about zero volts.

Another plasma cathode-based EBW system in the form of plasma cathode-based EBW system 300 having a second plasma cathode configuration is illustrated in FIG. 3. As shown, the plasma cathode-based EBW system 300 includes a housing 302 with a 302 plasma cathode chamber 304 that is rotated such that an +NSP electrode 316a and an −NSP electrode 316b are separated from one another along the x-direction and isolated from −E_{gun}. Thus, the housing axis A_{H} is approximately perpendicular to the axis of the plasma cathode chamber A_{PC}. The remaining components of the plasma cathode-based EBW system 300 of FIG. 3 can be the same as discussed above with respect to the plasma cathode-based EBW system 200 of FIG. 2, unless otherwise noted.

An advantage of the second configuration of the plasma cathode chamber 304 is that the plasma power supply output is symmetric relative to the electron gun voltage −E_{gun}. That is, −E_{gun} is connected to neutral voltage (common ground) output of the plasma power supply. Therefore, the plasma power supply does not require modification to implement the second configuration of the plasma cathode chamber 304. However, the plasma cathode chamber 304 and electron gun vacuum flange 344 can require modification versus their conventional design. In one aspect, modification can be required to include a fourth high voltage feedthrough, in addition to the three feedthroughs employed by the thermionic electron gun portion 230.

In another aspect, extraction of electrons from the plasma 242 and acceleration of electrons to the (grounded) anode 220 can require a new extractor electrode 308 and configuration. Generally, thermionic electron guns for electron beam welders use a Wehnelt electron optics design, where the thermionic cathode is biased at a high negative potential relative to the anode, in order to accelerate the electrons. In the second configuration of FIG. 3, the plasma electrodes +NSP 316a and −NSP 316b are biased independently of the gun's energy. Installation of a new electrode and cable are needed and biased at the −E_{gun} voltage. The new electrode is positioned at about the center of the plasma cathode chamber 304 to be physically balanced between the +NSP electrode and the —NSP electrode. The plasma cathode chamber 304 has an aperture 334′ aligned with an aperture 334 of the extractor electrode 208 to allow electron extraction. In order to satisfy the Wehnelt electron optics criteria, the new center electrode is positioned between the plasma cathode chamber 304 and the extractor electrode 308.

Table 1, below, illustrates operating parameters for the plasma cathode chamber 204 in the first configuration of FIG. 2 that can achieve extraction of an electron beam current of about 100 mA. The −NSP electrode 216b is electrically connected to the −E_{gun} voltage (e.g., about −60 kV). The extractor electrode 208 is biased within the range from about 400 V to about 1,000 V with respect to the −E_{gun} voltage to extract electrons from the plasma 242. The plasma 242 is driven by the pulsed high voltage supply, which is isolated and biased with respect to −E_{gun}. The extractor electrode 208 has an aperture 234′ to transmit the electrons to the anode 220, focusing coil 222, and deflection coil 224. As noted above, the anode, steering elements (e.g., the deflection coil 224), and the focusing elements (e.g., the focusing coil 222) can be similar to those used in a conventional e-beam welding gun. The listed operating parameters of the plasma cathode are applicable to all of the embodiments discussed herein (e.g., FIGS. 2, 3, and 4). The plasma excitation and beam extraction are independent of the configuration of the plasma cathode chamber 204.

TABLE 1
Operating parameters for extracted electron beam current of 100 mA

| Input | Description | Value | Units | Eqn |
|---|---|---|---|---|
| Te | Electron temperature in EHT plasma | 4 | eV | |
| V | Bias Ring accelerating potential | 400 | V | |
| n | Electron density at Bias Ring exit | 1.00E+17 | m³ | |
| d | Beam diameter at Bias Ring exit | 1 | mm | |
| dc | Beam diameter at EHT cathode exit | 0.5 | mm | |
| f | NSP operating frequency | 10 | kHz | |
| pw | NSP pulse width | 1.00E−07 | s | |
| ee | Electron creation energy in beam, per | 100 | eV | |
| | electron | | | |
| p | Fill pressure in region of EHT plasma | 10 | mT | |
| Constants and Conversions | | | | |
| m | Electron mass | 9.11E−31 | kg | |
| e | Electron charge | 1.60E−19 | C | |
| A | Beam area @ bias ring exit | 7.85E−07 | m² | |
| Ac | Cathode exit area | 1.96E−07 | m² | |
| t | NSP operating period | 0.0001 | s | |
| duty | NSP Duty cycle | 0.10 | % | |
| c | Speed of light | 3.00E+08 | m/s | |
| R | Universal gas constant | 8.31E+00 | J/mol*k | |
| Z | Number of atoms in gas | 2 | # | |
| Na | Avogadro's number | 6.02E+23 | #/mol | |
| Tn | Neutral gas temperature | 297 | k | |
| Calculations | | | | |
| vthe | Electron thermal velocity in EHT | 1E+06 | m/s | (8*Te/pi*m)^{1/2} |
| | plasma | | | |
| ve | Directed electron velocity from Bias | 1E+07 | m/s | (2eV/m)^{1/2} |
| | Ring acceleration | | | |
| Rvec | Ratio of directed electron velocity to | 4 | % | (ve)/c |
| | the speed of light | | | |
| I | Calculated beam current | 0.15 | A | enA(ve) |
| ne | Electron density of bulk steady state | 4E+18 | m⁻³ | I/(e(Ac)(vthe)) |
| | EHT plasma at EHT Cathode exit | | | |
| nep | Electron density of pulsed EHT | 4E+19 | m⁻³ | ne/duty |
| | plasma at EHT Cathode exit | | | |
| nd | Neutral particle density | 7E+20 | m⁻³ | PZ(Na)/R(Tn) |
| Ifs | Ionization fraction of bulk steady state | 1 | % | ne/nd |
| | EHT plasma | | | |
| Ifp | Ionization fraction of pulsed EHT | 5 | % | nep/nd |
| | plasma | | | |
| Pbe | Power into EHT plasma to create | 15 | W | I(ee) |
| | electrons | | | |

Notes and Assumptions

| | | | |
|---|---|---|---|
| Ir | Beam current required | 0.1 | A |
| | Exit holes are round | | |
| | All electrons that leave EHT plasma | | |
| | go through Bias Ring exit | | |
| | 1 electron per ion is generated | | |
| | Lower limit of Paschen curve for H2 is | | |
| | 0.9 Torr*cm, for 100 mTorr. Electron | | |
| | spacing is below 9 cm. | | |
| | Lower limit of Paschen curve for Ar is | | |
| | 0.25 Torr*cm, for 100 mTorr. | | |
| | Electron spacing is below 2.5 cm. | | |

Table 2, below, illustrates a maximum range of plasma operating conditions and output current and power for a 60 kV electron beam welding gun employing the plasma cathode. Plasma parameters for normal welding operations have a smaller range. For example, Table 1 gives exemplary parameters for 100 mA operation, which can produce an approximately 6 kW plasma electron beam. This is nominally the lowest power that is useful for welding. These operating parameters are applicable to all configurations of the plasma cathode discussed herein (e.g., FIGS. 2, 3, and 4). It can be understood, however, that embodiments of the disclosure are not limited to the disclosed operating parameters and other suitable operating parameters can be employed without limit.

TABLE 2
Operating parameters for 60 kV electron beam welding

| Parameter | Minimum | Maximum |
|---|---|---|
| Plasma power supply operating frequency (kHz) | 5 | 20 |
| Plasma power supply pulse width (nsec) | 0.1 | 5 |
| Plasma cathode chamber pressure (millitorr) | 1 | 100 |
| Bias ring voltage (V) | 400 | 1,000 |
| Output current (mA) | 16 | 1,000 |
| Welding power (kW) | 1 | 60 |

Additional operating arrangements are envisioned, as an example, for output power greater than about 60 kW. However, it can be understood that the plasma power supply would require modification to operate at higher output power of the plasma e-beam. Specifically, the power output would need to be increased to accelerate the plasma's higher electron flux.

As noted above, the plasma cathode-based EBW systems 200, 300 of FIGS. 2-3 can be retrofitted into the housing of existing thermionic cathode-based EBW systems with little to no modification. As an example, the 1 mm aperture of the anode, which is typical of Wehnelt bias rings in thermionic cathode-based EBW systems, can have a gas conductance of about 0.09 L/s. Under this condition, the differential pressure is given by Equation 1:

C_{ring}(P_{TC}−P_{WC})=S_{WC}*P_{WC} (1)

where C_{ring} is the gas conductance, P_{TC} is the pressure of the plasma cathode chamber, P_{WC} is the pressure of the welding chamber, and S_{WC} is the pumping speed of the welding chamber. For a pressure at 10 millitorr in the plasma cathode chamber, a pump generating less than about 1 liters per second can maintain an approximately one order of magnitude pressure differential between the plasma cathode chamber and the welding chamber, assuming no leaks, due to the time required for pressure transmission therebetween (e.g., between about 10 millitorr within the plasma cathode chamber and about 1 millitorr within the welding chamber). For a plasma pressure of about 100 millitorr, the pump speed is about 10 liters per second.

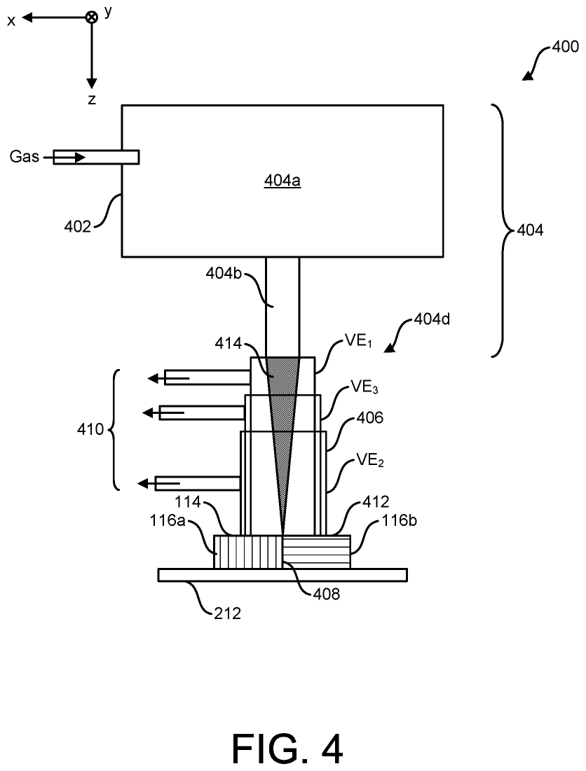

The ability of the cold plasma cathode to operate at relatively high pressure, compared to thermionic cathodes, also allows for the use of new configurations as well. FIG. 4 illustrates one exemplary embodiment of a differentially pumped plasma cathode-based EBW system 400. As shown, the differentially pumped EBW system 400 includes a housing 402 containing a plasma electron gun 404 and a multi-stage vacuum enclosure 406, referred to herein as a snorkel.

The plasma electron gun 404 of FIG. 4 includes an electron generation and extraction portion 404a and a focusing and steering portion 404b. The electron generation and extraction portion 404a can include the plasma cathode chamber, the plasma cathode, the anode, and extraction electrode. The focusing and steering portion can include the focusing coil and the deflection coil. Each of these components can operate as discussed above. In further embodiments, the plasma electrodes and the cathode chamber can be provided as discussed above with respect to the first configuration of FIG. 2 or the second configuration of FIG. 3.

The snorkel 406 includes a plurality of vacuum enclosures or stages. As shown, a first vacuum enclosure VE₁ is positioned at one end of the snorkel 406, adjacent to and in fluid communication with the focusing and steering portion 404b of the plasma electron gun 404. A second vacuum enclosure VE₂ is positioned at the opposing end of the snorkel 406. Optionally, one or more third vacuum enclosures VE₃ can be interposed between the first vacuum enclosure VE₁ and the second vacuum enclosure VE₂. Each of the vacuum enclosures VE₁, VE₂, VE₃ is further in fluid communication with a dedicated vacuum pump (not shown) via respective vacuum lines 410.

The walls that separate respective ones of the vacuum enclosures VE₁, VE₂, VE₃ extend from the plasma electron gun 404 (e.g., a distal end of the plasma electron gun 404d) to the surface of the components to be welded (the work piece 114). So configured, each vacuum enclosure VE₁, VE₂, VE₃ of the snorkel 406 can maintain an approximately constant pressure that is different than an adjacent (e.g., nearest neighbor) vacuum enclosure. Thus, a predetermined pressure gradient can be established from the work piece 114 to the plasma electron gun 404. That is, between the second vacuum enclosure VE₂ and the first vacuum enclosure VE₁. As an example, the pressure within the second enclosure VE₂ can be less than the pressure within the first enclosure VE₁. When present, the pressure within the third enclosure(s) VE₃ is intermediate to the pressure of the first enclosure VE₁ and the second enclosure VE₂. The plasma cathode chamber can be isolated by use of a small aperture of the extractor electrode (e.g., about 1 mm diameter).

In use, the snorkel 406 (e.g., a distal end of the second vacuum enclosure VE₂) can be placed in contact with an outer surface of the work piece, 114 adjacent to the location of the incipient weld 408 and forms a vacuum seal 412. Thus, the portion of work piece 114 adjacent to the weld 408 is held at a pressure approximately equal to VE₂. An electron beam 414 extracted from the plasma cathode is transmitted through the focusing and steering portion 404b in a moderate vacuum (e.g., up to several torr) and is incident upon the weld 408. The snorkel 406 is mounted on an alignment stage (not shown) and can be moved along the weld seam using an alignment structure (e.g., a hexapod support). The pressure within the snorkel 406 is low enough to allow the electron beam 414 to be transmitted from the plasma electron gun 404 to the work piece 114 with minimal beam divergence and absorption. Because the portion of the work piece 114 adjacent the weld 408 is maintained at about the pressure of the second vacuum enclosure VE₂, the stage and other work piece positioning mechanisms can be at about atmospheric pressure or in a controlled environment, such as a dry argon glove box.

Embodiments of the snorkel 406 can adopt a variety of configurations. In one aspect, the number of vacuum enclosure segments can range from at least 2 (e.g., the third vacuum enclosure(s) VE₃ are omitted) to 6 or more (e.g., the first vacuum enclosure VE₁, the second vacuum enclosure VE₂ and four or more third vacuum enclosures VE₃), depending upon the desired pressure gradient between the work piece 114 and the plasma electron gun 404.

In general, a snorkel 406 having a greater number of vacuum enclosure segments allows more zones of constant pressure to be established between the second vacuum enclosure VE₂ and the first vacuum enclosure VE₁ and a smaller rate of change of pressure along the beam axis within the snorkel 406. In the case of two vacuum enclosure segments, the rate of pressure change between the first vacuum enclosure VE₁ and the second vacuum enclosure VE₂ can be relatively large, and result in significant turbulence between the second enclosure VE₂ in fluid communication with a high speed pump and the first vacuum chamber VE₁ in which the electron beam 414 is transmitted to the welding joint. This turbulence can cause the plasma electron beam 414 to diverge, which creates a wider weld 408. By adding more vacuum enclosures to the snorkel 406 (e.g., increasing the number of third vacuum enclosures VE₃) the rate of change of pressure along the beam axis within the snorkel 406 can be decreased, reducing the turbulence at the electron beam aperture.

One exemplary embodiment of the snorkel of FIG. 4 can include three vacuum enclosures VE₁, VE₂, VE₃, and the pressure in each vacuum enclosure can be provided as follows. In general, the vacuum enclosures are configured to create a differential pressure between atmospheric pressure outside of the snorkel 406 to the first vacuum enclosure VE₁, which has the lowest pressure. In one embodiment, the second vacuum enclosure VE₂ can be at a pressure of about 100 millitorr, the third vacuum enclosure VE₃ can be at a pressure of about 500 millitorr, the first vacuum enclosure VE₁ can be at a pressure of about 1 millitorr. The environment outside of the snorkel (e.g., containing the stage) can be at approximately atmospheric pressure (e.g., about 760 millitorr).

In a further aspect, under circumstances where the first and second components 116a, 116b to be welded have large, smooth surfaces, the diameter of an aperture of the anode can be relatively large (e.g., about 100 cm in diameter). In this case, the diameter of the anode aperture can be designed to span a large weld joint. The deflection coil can be configured to deflect the plasma electron beam 414 to track the weld.

In another aspect, under circumstances where the first and second components 116a, 116b to be welded have irregular surfaces, it can be difficult to form a reliable vacuum seal 412 between a large outer pumping zone (e.g., vacuum enclosure VE₂) and the work piece 114. In this circumstance, the outer pumping zone seal can be too small to steer the electron beam 414 along the weld joint geometry. The VE₁ aperture to transmit the electron beam 414 to the weld 408 can be relatively small (e.g., about 2 cm to about 3 cm). In this case, the snorkel 406 can be moved to track the weld 408, rather than steering the plasma electron beam 414.

Irregular work piece surfaces can also create difficulty in controlling the welding process. In general, it is desirable for welding parameters, such as the size of the weld 408 and the temperature of the welding process, to be approximately constant in order to achieve uniformity of the weld 408 along its length. However, the welding parameters are dependent, at least in part, upon the size of the focal region. When the snorkel 406 moves over an irregular surface (e.g., a hill or a valley), a working distance between the work piece 114 and the electron gun 404 changes, which in turn changes the size of the focal region.

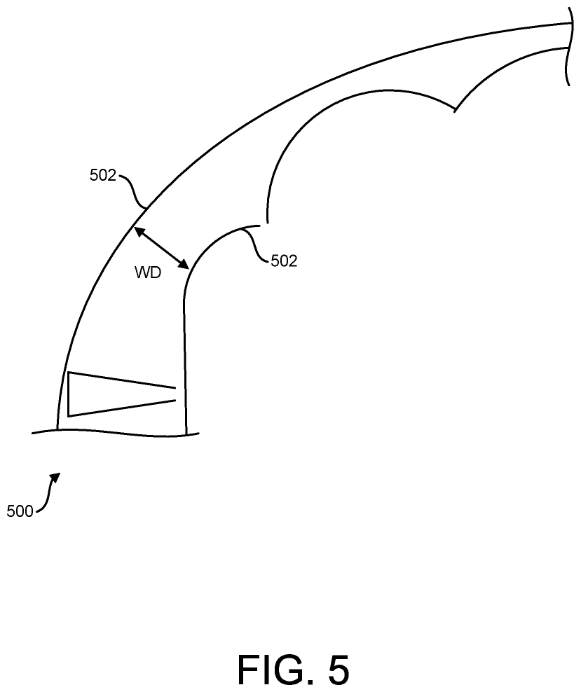

Recognizing that irregular surfaces can change the size of the focal region, and result in non-uniform of welds, additional embodiments of the plasma cathode-based EBW system 400 of FIG. 4 can be modified to dynamically adjust focusing of the plasma electron beam 414 in order to maintain an approximately constant focal region size at the work piece surface. As shown in FIG. 5, the plasma cathode-based EBW system of FIG. 4 is modified include a telescoping snorkel 500.

The telescoping snorkel 500 is configured to change length in response to changes in the height of the work piece surface. As an example, the vacuum enclosures of the telescoping snorkel 500 can included sliding seals configured to slide in the direction of the housing axis A_{H}, retracting when a distal end of the second vacuum enclosure VE₂ contacts a raised portion of the work piece surface and extending when the distal end of the second vacuum enclosure VE₂ contacts a recessed portion of the work piece surface. In this manner, the vacuum enclosures adjust to the change of working distance WD between the plasma electron gun 404 and the work piece 114.

In use, the telescoping snorkel 500 can be mounted to a support structure 502 (e.g., a robotic arm, gantry, hexapod structure, track rail, etc.) that is installed above the surface of the work piece 114. The support structure 502 can be configured to move the cathode-based EBW system with respect to the work piece 114. As shown in FIG. 5, the support structure 502 is a rail and the cathode-based EBW system is moved in a path along the rail (e.g., a circular path). For clarity, only the telescoping snorkel 500 is shown. The path of the gun rail can be taken as the distal end of the plasma electron gun 404 (e.g., the end of the plasma electron gun 404 closest to the work piece 114), while a weld contour path 504 can be taken as the surface of the work piece 114. It can be observed that the working distance WD changes as the telescoping snorkel 500 moves along the gun rail.

Beneficially, embodiments of the differentially-pumped plasma-cathode based EBW systems of FIGS. 4-5 can eliminate the need for a large, high-vacuum enclosure, in contrast to conventional thermionic-based EBW systems.

Certain exemplary embodiments have been described to provide an overall understanding of the principles of the structure, function, manufacture, and use of the systems, devices, and methods disclosed herein. One or more examples of these embodiments have been illustrated in the accompanying drawings. Those skilled in the art will understand that the systems, devices, and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention. Further, in the present disclosure, like-named components of the embodiments generally have similar features, and thus within a particular embodiment each feature of each like-named component is not necessarily fully elaborated upon.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

One skilled in the art will appreciate further features and advantages of the invention based on the above-described embodiments. Accordingly, the present application is not to be limited by what has been particularly shown and described, except as indicated by the appended claims. All publications and references cited herein are expressly incorporated by reference in their entirety.

1. A system, comprising:
an electron gun including a cold cathode electron source and an extraction electrode;
a focusing system configured to focus a beam of electrons extracted from the electron gun to a focal region; and
a housing including the electron gun and extend along a housing axis in the direction of the electron beam;
wherein the cold cathode source is configured to emit electrons at a first operating pressure that is higher than a second operating pressure at the focal region of the electron beam.

2. The system of claim 1, wherein the cold cathode electron source is a plasma cathode includes:
a plasma cathode chamber;
a first plasma electrode mounted to a first wall of the plasma cathode chamber; and
a second plasma electrode mounted to a second wall of the plasma cathode chamber, opposite the first wall;
wherein an axis of the plasma cathode chamber extends in the direction between the first and second plasma electrodes.

3. The system of claim 2, wherein the plasma cathode is configured to generate a plasma having an electron temperature less than about 200° C.

4. The system of claim 2, wherein the plasma cathode chamber axis is approximately aligned with the housing axis.

5. The system of claim 2, wherein the plasma cathode chamber axis is approximately perpendicular to the housing axis.

6. The system of claim 1, wherein the first operating pressure within the range from about 50 millitorr to about 500 millitorr.

7. The system of claim 6, wherein the second operating pressure is within the range from about 1 millitorr to about 50 millitorr.

8. The system of claim 1, wherein the housing includes the electron gun and a welding chamber enclosing the focal region.

9. The system of claim 1, wherein the housing further comprises a differentially pumped snorkel extending between a first end coupled to the electron gun and a second free end, wherein the snorkel is configured to provide a selected pressure gradient between the first end and the second end, and wherein the focal region is approximately positioned at the second free end.

10. The system of claim 9, wherein the snorkel comprises a plurality of vacuum enclosures, each in fluid communication with a respective vacuum pump.

11. A method, comprising:
generating, by an electron gun including a cold cathode source and an extraction electrode, electrons at a first pressure;
extracting, by the extraction electrode, a electrons emitted from the cold cathode source;
focusing a beam of the extracted electrons to a focal region along an axis of a housing containing the electron gun; and
receiving, incident upon a surface of the work piece, the focal region of the electron beam, wherein a second pressure at the work piece is less than the first pressure.

12. The method of claim 11, wherein generating the electrons comprises:
receiving a flow of gas within a plasma cathode chamber of the electron gun; and
generating an electric field between a first plasma electrode mounted to a first wall of the plasma cathode chamber and a second plasma electrode mounted to a second wall of the plasma cathode chamber, opposite the first wall, wherein the electric field is configured to form a plasma from the gas;
wherein an axis of the plasma cathode chamber extends in the direction between the first and second plasma electrodes.

13. The method of claim 11, wherein the generated plasma has an electron temperature less than about 200° C.

14. The method of claim 12, wherein the plasma cathode chamber axis is approximately aligned with the housing axis.

15. The method of claim 12, wherein the plasma cathode chamber axis is approximately perpendicular to the housing axis.

16. The method of claim 12, wherein the first pressure is within the range from about 50 millitorr to about 500 millitorr.

17. The method of claim 16, wherein the second pressure is within the range from about 1 millitorr to about 50 millitorr.

18. The method of claim 11, further comprising enclosing the work piece within a welding chamber, wherein the welding chamber is in fluid communication with the electron gun.

19. The method of claim 11, further comprising:
forming a vacuum seal between a surface of the work piece and a free end of a snorkel, the snorkel extending from the free end to the electron gun; and
establishing a selected pressure gradient along the length of the snorkel between the electron gun and the free end.

20. The method of claim 19, wherein establishing the selected pressure gradient comprises applying vacuum pressure of different levels to respective vacuum enclosures of the snorkel.
